(19) United States
(12) Patent Application Publication
(10) Pub. No.: US 2011/0228605 A1
(43) Pub. Date: Sep. 22, 2011

(54) NONVOLATILE MEMORY

(75) Inventors: Takahiro SUZUKI, Chigasaki-Shi (JP); Tomoko Araya, Fujisawa-Shi (JP)

(73) Assignee: Kabushiki Kaisha Toshiba, Tokyo (JP)

(21) Appl. No.: 13/050,418

(22) Filed: Mar. 17, 2011

(30) Foreign Application Priority Data
Mar. 19, 2010 (JP) 2010-063931

(51) Int. Cl. G11C 16/08

(52) U.S. Cl. 365/185.09

(57) ABSTRACT

A nonvolatile memory includes a memory cell array comprising an object block which includes a first data bit region capable of storing input data and a first flag bit region capable of storing first flag information, a redundant block which includes a second data bit region capable of storing input data and a second flag bit region capable of storing second flag information, and a special block including a special bit region capable of storing an object block address of the object block. The nonvolatile memory includes an object block retention part which retains the object block address. The nonvolatile memory includes an object block flag storage part which stores the first flag information therein. The nonvolatile memory includes a redundant block flag storage part which stores the second flag information. The nonvolatile memory includes a coincidence detection circuit which detects whether a block address which is input coincides with the object block address retained in the object block retention part. The nonvolatile memory includes a block changeover circuit which controls selection of one of the object block and the redundant block on the basis of the first and second flag information when the coincidence detection circuit has detected that the input block address coincides with the object block address.

### CROSS-REFERENCE TO RELATED APPLICATION

This application is based upon and claims the benefit of priority from the prior Japanese Patent Application No. 2010-63931, filed on Mar. 19, 2010, the entire contents of which are incorporated herein by reference.

### BACKGROUND

1. Field

Embodiments described herein relate generally to a nonvolatile memory such as a flash memory.

2. Background Art

As the performance of computers has become higher in recent years, handled data becomes larger in volume and diversified.

It is required for such data, depending on its nature, to have higher reliability or a longer life. In some cases, data are stored in a nonvolatile memory which is used as a storage medium and represented by a flash memory.

In general, in the flash memory, electrons are injected into a floating gate through a tunnel oxide layer by writing data. Therefore, every time rewriting is conducted, the tunnel oxide layer is degraded. A block including a plurality of cells which have degraded in this way will become a defective block. If the memory is used under the condition in which writing and erasing are concentrated to a specific block, a product life might expire earlier.

As a method for avoiding such a situation, there is wear leveling. For example, there are a method for dispersing rewriting by using an algorithm for managing the number of times of rewriting in a block on the memory controller side to avoid the concentration, and a method for managing the number of times of rewriting as a ring buffer and using blocks on the average. Furthermore, in some conventional nonvolatile memories, elapse time of the erase operation is managed and defective cells are replaced by redundant cells according to the elapse time.

### BRIEF DESCRIPTION OF THE DRAWINGS

FIG. 1 is a block diagram showing an example of the configuration of a nonvolatile memory (a NAND-type flash memory) 100 according to a first embodiment;

FIG. 2 is a block diagram obtained from the nonvolatile memory 100 shown in FIG. 1 by paying attention to a configuration for automatically dispersing the number of times of rewriting;

FIG. 3 is a diagram showing an example of a format which specifies a redundant block of a dedicated command (command for setting);

FIG. 4 is a diagram showing an example of a format which does not specify a redundant block of a dedicated command (command for setting);

FIG. 5 is a diagram showing an example of a format of a dedicated command (command for clearing) in the case where a redundant block is specified;

FIG. 6 is a diagram showing an example of a format of a dedicated command (command for clearing) in the case where a redundant block is not specified;

FIG. 7 is a diagram showing an example of a format of a data column of block changeover information which becomes initial setting information at the time when the power supply is turned on;

FIG. 8 is a diagram showing another example of the format of the data column of block changeover information which becomes initial setting information at the time when the power supply is turned on;

FIG. 9 is a diagram showing an example of a readout sequence of block changeover information and flag information at the time when the power supply is turned on;

FIG. 10 is a diagram showing voltage relations at the time when flag information stored in the flag bit region 1c in the block A in the memory cell array 1 shown in FIG. 2 is read out;

FIG. 11 is a diagram showing an example of a sequence of flag information setting at the time of an erase operation;

FIG. 12 is a diagram showing an example of relations between logics of flag latches and blocks to be accessed;

FIG. 13 is a diagram showing a sequence of a method for generating flag information and writing the flag information into the block and the flag latch when erasing data in the block;

FIG. 14 is a diagram showing an example of a sequence for setting flag information into a selected block at the time of a write operation;

FIG. 15 is a diagram showing an example of a sequence for setting flag information into flag latches at the time of an erase operation;

FIG. 16 is a diagram showing an example of relations between logics of the flag latches and blocks to be accessed; and

FIG. 17 is a diagram showing a sequence of a method for generating flag information and writing the flag information into the block when writing data into the block.

### DETAILED DESCRIPTION

A nonvolatile memory according to an embodiment includes a memory cell array comprising an object block which includes a first data bit region capable of storing input data and a first flag bit region capable of storing first flag information, a redundant block which includes a second data bit region capable of storing input data and a second flag bit region capable of storing second flag information, and a special block including a special bit region capable of storing an object block address of the object block. The nonvolatile memory includes an object block retention part configured to retain the object block address. The nonvolatile memory includes an object block flag storage part configured to store the first flag information therein. The nonvolatile memory includes a redundant block flag storage part configured to store the second flag information. The nonvolatile memory includes a coincidence detection circuit configured to detect whether a block address which is input coincides with the object block address retained in the object block retention part. The nonvolatile memory includes a block changeover circuit configured to control selection of one of the object block and the redundant block on the basis of the first and second flag information when the coincidence detection circuit has detected that the input block address coincides with the object block address.

Hereafter, embodiments will be described with reference to the drawings.

### First Embodiment

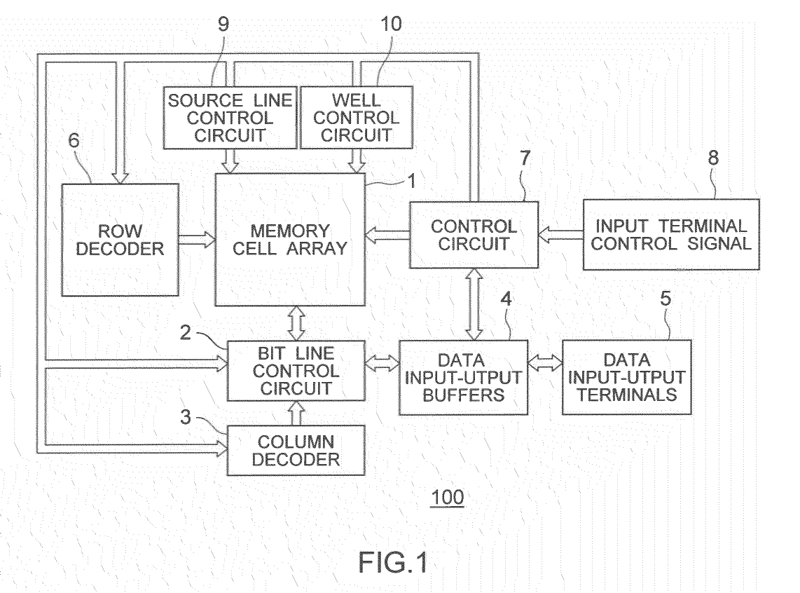

FIG. 1 is a block diagram showing an example of the configuration of a nonvolatile memory (a NAND-type flash memory) 100 according to a first embodiment.

As shown in FIG. 1, the NAND-type flash memory 100 includes a memory cell array 1, a bit line control circuit 2, a column decoder 3, a data input/output buffer 4, a data input/output terminal 5, a row decoder 6, a control circuit 7, a control signal input terminal 8, a source line control circuit 9, and a well control circuit 10.

The memory cell array 1 includes a plurality of bit lines, a plurality of word lines, and a source line. This memory cell array 1 includes a plurality of blocks in which memory cells, into which data is electrically rewritable, formed from EEPROM cells are disposed in a matrix pattern.

The bit line control circuit 2 used for controlling the voltages of bit lines and the row decoder 6 used for controlling the voltages of the word lines are connected to this memory cell array 1. In a write operation of data, one block is selected by the row decoder 6, and the other blocks are in a non-selection state.

This bit line control circuit 2 reads data of a memory cell of the memory cell array 1 through the bit line, detects the status of the memory cell through the bit line, or writes data into the memory cell by applying a write control voltage to the memory cell through the bit line.

In addition, the bit line control circuit 2, the column decoder 3 and the data input/output buffer 4 are connected each other. The data storage circuit disposed in the bit line control circuit 2 is selected by the column decoder 3, and the data of the memory cell that is read out by the data storage circuit is output to the outside thereof from the data input/output terminal 5 through the data input/output buffer 4.

In addition, write data input from the outside to the data input/output terminal 5 is stored in the data storage circuit that is selected by the column decoder 3 through the data input/output buffer 4. From the data input/output terminal 5, various commands such as a write, a read, an erase, and a status read and an address other than the write data are also input.

The row decoder 6 is connected to the memory cell array 1. This row decoder 6 applies a voltage that is necessary for read, write, or erase to a word line of the memory cell array 1.

The source line control circuit 9 is connected to the memory cell array 1. This source line control circuit 9 is configured so as to control the voltage of the source line SRC.

The well control circuit 10 is connected to the memory cell array 1. This well control circuit 10 is configured so as to control the voltage of a semiconductor substrate (well) in which the memory cells are formed.

The control circuit 7 is configured so as to control the memory cell array 1, the bit line control circuit 2, the column decoder 3, the data input/output buffer 4, the row decoder 6, the source line control circuit 9, and the well control circuit 10. That is, the control circuit 7 has a function of generally controlling the overall operation of the NAND-type flash memory 100.

Here, the control circuit 7 includes a voltage booster circuit (not shown) that raises the voltage of a power source voltage. The control circuit 7 is configured so as to raise the voltage of the power source voltage as necessary by using the voltage booster circuit and supply a resultant voltage to the bit line control circuit 2, the column decoder 3, the data input/output buffer 4, the row decoder 6, the source line control circuit 9, and the well control circuit 10.

This control circuit 7 controls operation according to control signals (a command latch enable signal CLE, an address latch enable signal ALE, a ready/busy signal RY/BY, or the like) that are input from the outside through the control signal input terminal 8 and a command that is input from the data input/output terminal 5 through the data input/output buffer 4. In other words, when data is programmed, verified, read, and erased according to the control signals and the command, the control circuit 7 generates a desired voltage and supplies the resultant voltage to the memory cell array 1.

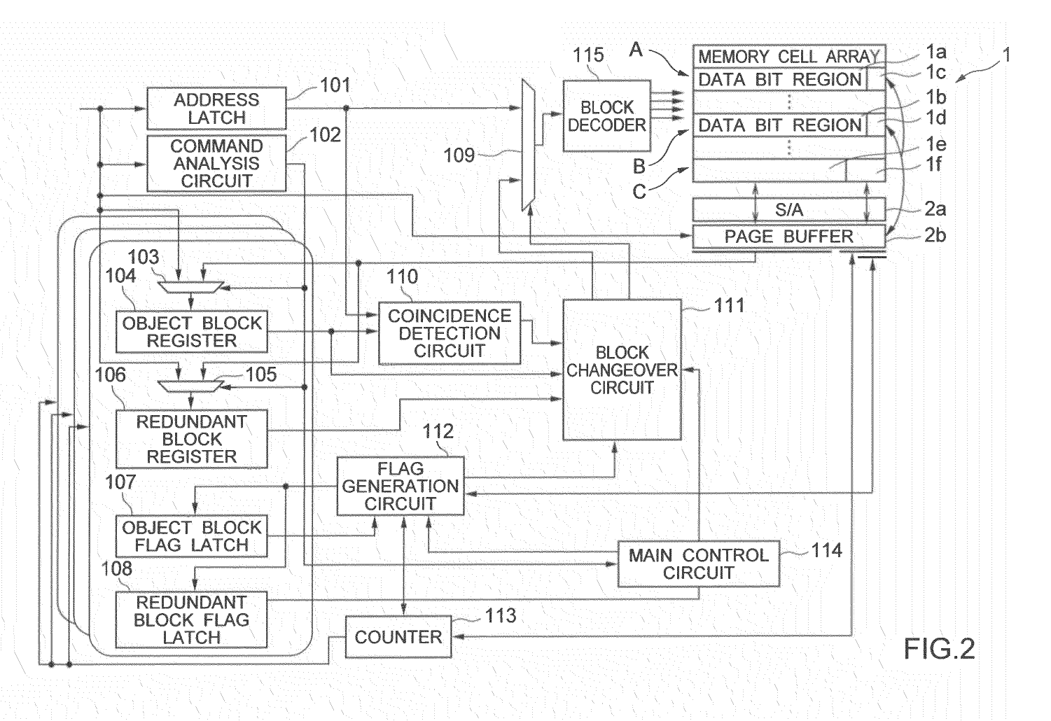

FIG. 2 is a block diagram obtained from the nonvolatile memory 100 shown in FIG. 1 by paying attention to a configuration for automatically dispersing the number of times of rewriting.

In FIG. 2, an address latch 101, a command analysis circuit 102, a multiplexer 103, an object block register 104, a multiplexer 105, a redundant block register 106, an object block flag latch 107, a redundant block flag latch 108, a multiplexer 109, a coincidence detection circuit 110, a block changeover circuit 111, a flag generation circuit 112, a counter 113, and a main control circuit 114 are included in the control circuit 7 shown in FIG. 1.

By the way, the memory cell array 1 includes a block A, a block B, and a special block C.

Here, the block A is defined as, for example, an object block which is limited in the number of times of rewriting and which includes a data bit region is capable of storing input data and a flag bit region 1c capable of storing flag information.

Here, the block B is defined as, for example, a redundant block which includes a data bit region 1b capable of storing input data and a flag bit region 1d capable of storing flag information. The redundant block B is adapted to not to allow its address to be specified by, for example, an external command.

The block C is defined as a special block including a special bit region 1e capable of storing an object block address of the object block A and a redundant block address of the redundant block B and a special bit region 1f capable of storing index information.

The object block register (object block retention part) 104 is adapted to retain the object block address.

The redundant block register (redundant block retention part) 106 is adapted to retain the redundant block address.

The object block flag latch (object block flag storage part) 107 is adapted to latch (store) flag information concerning the selected object block.

The redundant block flag latch (redundant block flag storage part) 108 is adapted to latch (store) flag information concerning the selected redundant block.

The coincidence detection circuit 110 is adapted to detect whether the block address which has been input coincides with the object block address retained in the object block register 104.

A block decoder 115 is adapted to select a block in the memory cell array 1.

Upon detecting coincidence between the input block address and the object block address in the coincidence detection circuit 110, the block changeover circuit 111 is adapted to control the block decoder 115 so as to select either the object block A or the redundant block B by using the object block address or the redundant block address on the basis of the flag information.

The flag generation circuit 112 is adapted to generate flag information, latch the flag information in the object block flag latch 107 and the redundant block flag latch 108, and transfer the flag information to a page buffer 2b.

In FIG. 2, the block decoder 115 is included in the row decoder 6.

In FIG. 2, a sense amplifier 2a and the page buffer 2b are included in the bit line control circuit 2.

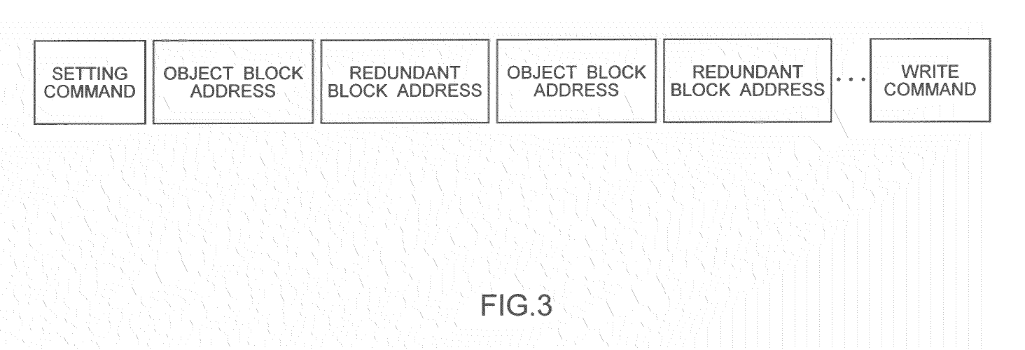

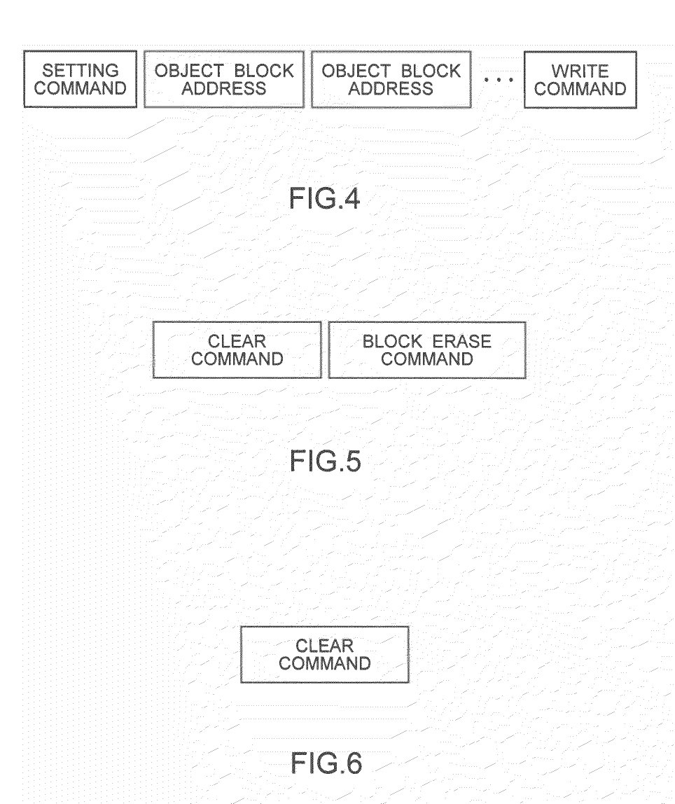

FIG. 3 is a diagram showing an example of a format which specifies a redundant block of a dedicated command (command for setting). FIG. 4 is a diagram showing an example of a format which does not specify a redundant block of a dedicated command (command for setting). FIG. 5 is a diagram showing an example of a format of a dedicated command (command for clearing) in the case where a redundant block is specified. FIG. 6 is a diagram showing an example of a format of a dedicated command (command for clearing) in the case where a redundant block is not specified.

By using the format shown in FIG. 3, an object block to be used at a high frequency and a redundant block are set by the command for setting.

In other words, the command for setting is analyzed by the command analysis circuit 102, and an object block address of the object block to be used at a high frequency is input to the object block register 104 via the multiplexer 103 and retained therein. The object block address is retained in the object block register 104 in order to make a decision whether a block to be accessed is the object block. In addition, a redundant block address of the redundant block specified as a changeover destination is input to the redundant block register 106 via the multiplexer 105 and retained therein.

By the way, as for the number of blocks which is set by the command for setting, it is supposed that blocks corresponding to a finite number of sets can be input.

In addition, block changeover information including the object block address, the redundant block address, and a count value (index information) which is set in the counter 113 is transferred to the page buffer 2b which accumulates write data. The block changeover information transferred to the page buffer 2b is stored in the special bit regions 1e and 1f of special blocks (blocks which are not selected by an ordinary block address) in the memory cell array 1 selected by a dedicated command via the sense amplifier 2a.

This block changeover information is used to restore the setting when the power supply is turned on.

In the case of a format which does not specify a redundant block, the redundant block address is omitted as shown in FIG. 4.

The case where a block erasing command is provided independently and a block address is erased according to this block erasing command as shown in FIG. 5, and the case where a block address is erased according to a command for clearing as shown in FIG. 6 are supposed.

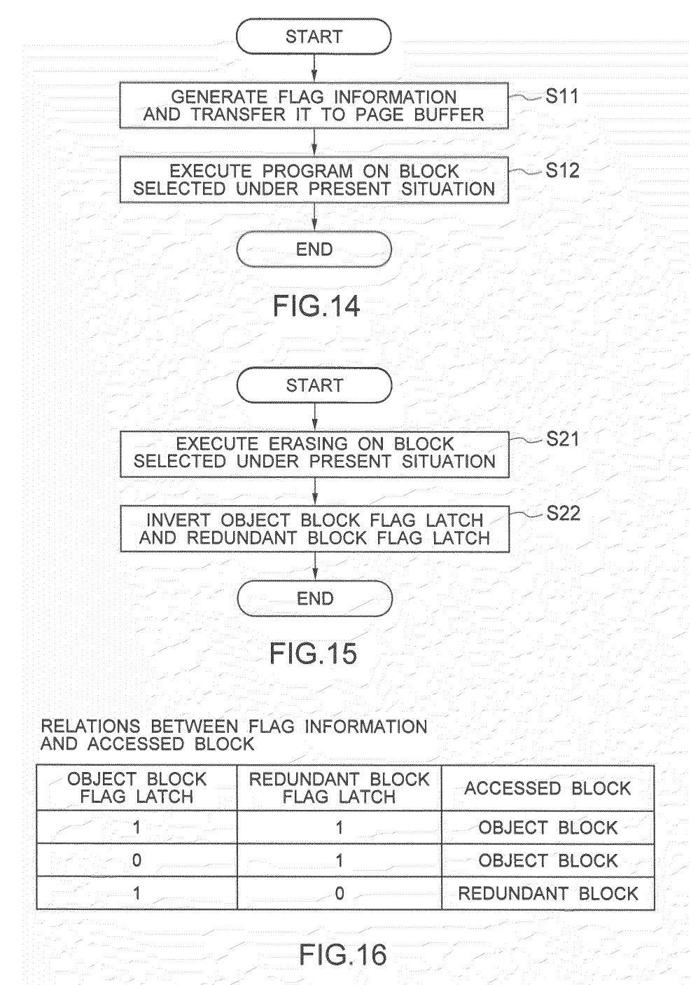

In FIGS. 3 and 4, a write command is a command for writing a flag of block changeover information used in an operation which will be described later with reference to FIGS. 14 to 17.

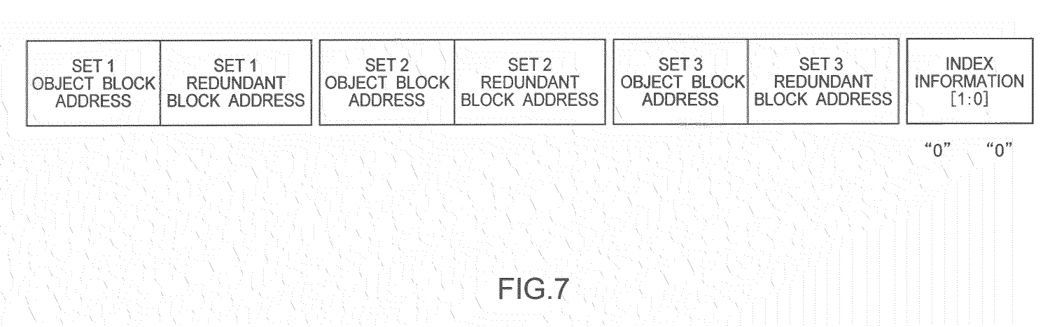

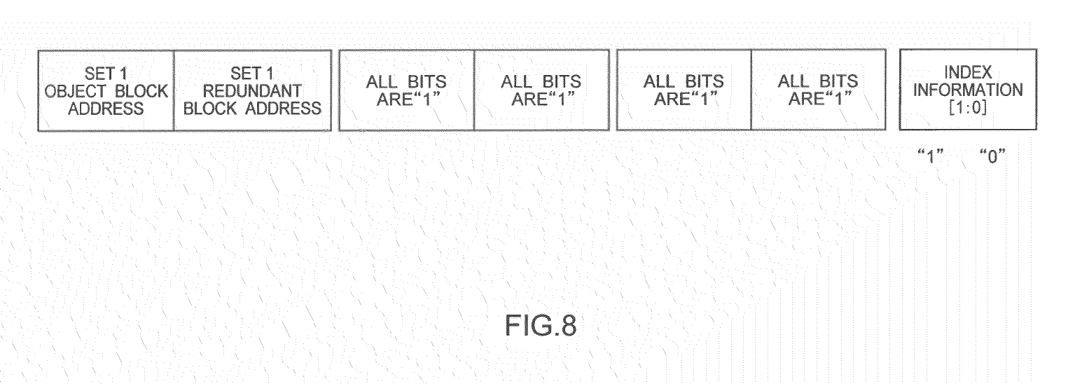

FIG. 7 is a diagram showing an example of a format of a data column of block changeover information which becomes initial setting information at the time when the power supply is turned on. FIG. 8 is a diagram showing another example of the format of the data column of block changeover information which becomes initial setting information at the time when the power supply is turned on.

As shown in FIG. 7, for example, data to be written includes three sets of the object block address, three sets of the redundant block address, and index information (bit data) which indicates the number of sets to be used. By the way, the index information (bit data) 00 indicates “3” sets.

As shown in FIG. 8, for example, data to be written includes one set of the object block address and the redundant block address, and index information (bit data) which indicates the number of sets to be used. By the way, the index information (bit data) 10 indicates “1” set. Furthermore, in all columns in which an address is not specified, data “1” is set.

The index information is added by a circuit included in the nonvolatile memory 100.

In the case of the type in which no redundant block is specified as shown in FIG. 4, the block changeover circuit 111 may invalidate the operation of the block decoder 115 and control a selection signal of dedicated redundant blocks prepared redundantly, on the basis of a signal which has been output by the coincidence detection circuit 110 upon detecting that a block specified in address coincides with an object block. Alternatively, the block changeover circuit 111 may select the redundant block by using the block decoder 115.

As a result, changeover from the object block is conducted, and a program operation is executed with respect to the dedicated block corresponding to the redundant block.

An example of setup at the time when the power supply is turned on will now be described. The case where an object block and a redundant block are set will now be described.

It is necessary to read out the block changeover information and flag information when the power supply is turned on, supposing the time when starting the restart operation after the power supply is turned off.

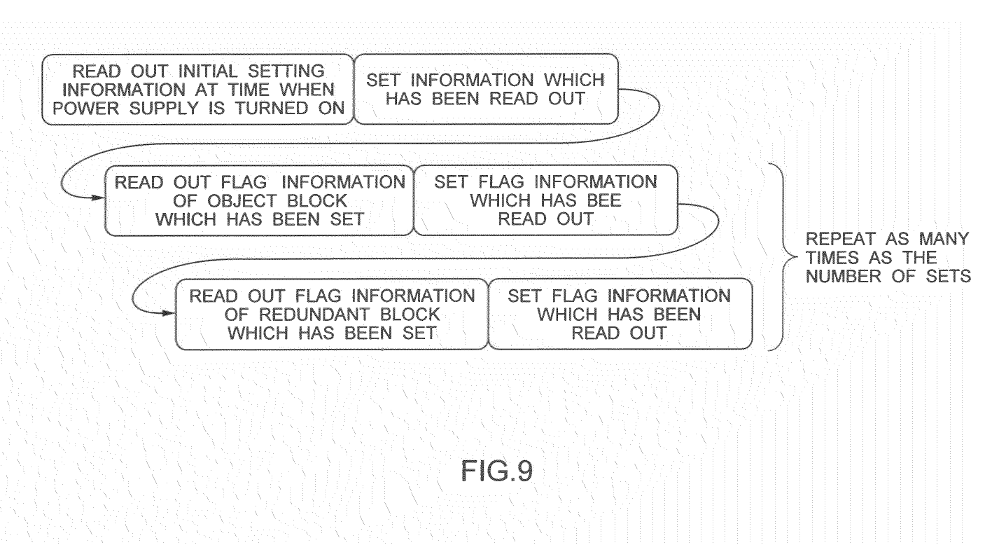

FIG. 9 is a diagram showing an example of a readout sequence of block changeover information and flag information at the time when the power supply is turned on.

As shown in FIG. 9, block changeover information which is initial setting information at the time when the power supply is turned on is first read out from the special bit regions 1e and 1f in the special block.

In the block changeover information which has been read out, the object block address is set in the object block register 104, the redundant block address is set in the redundant block register 106, and the index information is set in the counter 113.

As shown in FIG. 9, the flag information in the object block and the flag information in the redundant block are read out. The flag information is history information used to change over an object to be programmed between an object block and a redundant block at every time an erase operation of an object block seen from the external viewpoint is performed. The flag information is represented by bit data.

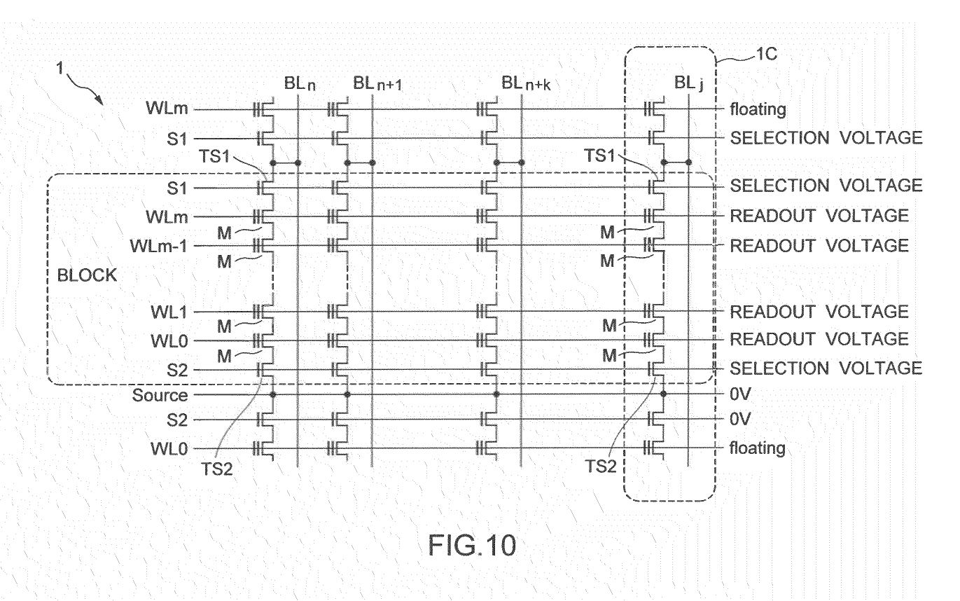

FIG. 10 is a diagram showing voltage relations at the time when flag information stored in the flag bit region is in the block A in the memory cell array 1 shown in FIG. 2 is read out. By the way, voltage relations at the time when flag information stored in the flag bit region 1d in the block B in the memory cell array 1 shown in FIG. 2 are similar to them.

In ordinary data readout, a readout voltage is applied to a word line to be read and a non-selection voltage is applied to other word lines in order to read data from a memory cell transistor M connected to the selected word line in the block.

On the other hand, flag information is information for a block. As shown in FIG. 10, therefore, a selection readout voltage is applied to all word lines WL0 to WLm and a selection voltage is applied to selection gate lines S1 and S2. As a result, readout can be conducted to detect whether even one flag information piece (even one bit) is already written in memory cell transistors M connected to a bit line BLj for flag storage.

Flag information read out from the object block is set in the object block flag latch 107 via the sense amplifier 2a, the page buffer 2b, and the flag generation circuit 112.

Flag information read out from the redundant block is set in the redundant block flag latch 108 via the sense amplifier 2a, the page buffer 2b, and the flag generation circuit.

It becomes possible to restore information which represents whether a block having been written lastly when the power supply is turned off is an object block or a redundant block, on the basis of the flag information.

Since a value (index information) which is set in the counter 113 means the number of sets, setting of the block changeover information and flag information is conducted repeatedly as many times as a value which is set in the counter 113. The value which is set in the counter 113 indicates the number of sets of the object block and redundant block. Therefore, the above-described operation is executed until 0 is reached by decrementing from the value which is set or until a value obtained by incrementing the counter value coincides with a value which is set on the basis of the index information as a result of comparison. In the example shown in FIG. 2, 3 is set as the value.

In the case of the type already described in which no redundant block is specified, an object block flag is set only in the object block flag latch 107.

An example of a method for changing over blocks will now be described. For example, it is supposed that the block A is specified in the object block and the block B is specified in the redundant block. In addition, it is supposed that writing into the redundant block B has been conducted (or the redundant block B is the object of writing).

If the address of the object block A is input from the external, then the coincidence detection circuit 110 is activated. And the coincidence detection circuit 110 outputs a signal (the number of signals as many as the number of sets) depending upon whether an object block address in which set coincides with the block address which is input, to the block changeover circuit 111. As a result, the block changeover circuit 111 obtains information as to whether the input block address coincides with the address of the object block A.

In addition, the flag generation circuit 112 generates a signal indicating which of the object block A and the redundant block B should be used based on logics of the object block and the redundant block, and outputs the signal to the block changeover circuit 111.

The redundant block register 106 outputs the address of the redundant block B to the block changeover circuit 111.

From among these signals, the block changeover circuit 111 outputs the address of the redundant block B to be output to the block decoder 115 and a control signal for selecting the address of the redundant block B and conducting changeover, to the multiplexer 109. As a result, the address of the redundant block B is input to the block decoder 115, and a program operation is executed with respect to the redundant block B.

The main control circuit 114 manages an operation of the memory cell array 1 according to a command signal for every operation sent from the command analysis circuit 102, and controls operations of the block changeover circuit 111, the flag generation circuit 112, and the counter 113. While controlling the operation of the memory cell array 1 according to the command signal, the main control circuit 114 controls the flag generation circuit 112 as to the timing of changing over the flag information.

Generation of the flag information differs in control depending upon whether the flag information is generated when writing data into a block or the flag information is generated when erasing data from a block. Two examples depending upon the difference in generation will be described.

First, an example of a method for generating and writing flag information when erasing data in a block will now be described.

According to this method, the changeover situation between the object block and the redundant block before and after turning on and turning off the power supply can be restored completely. In other words, the flag information is altered when conducting the erase operation.

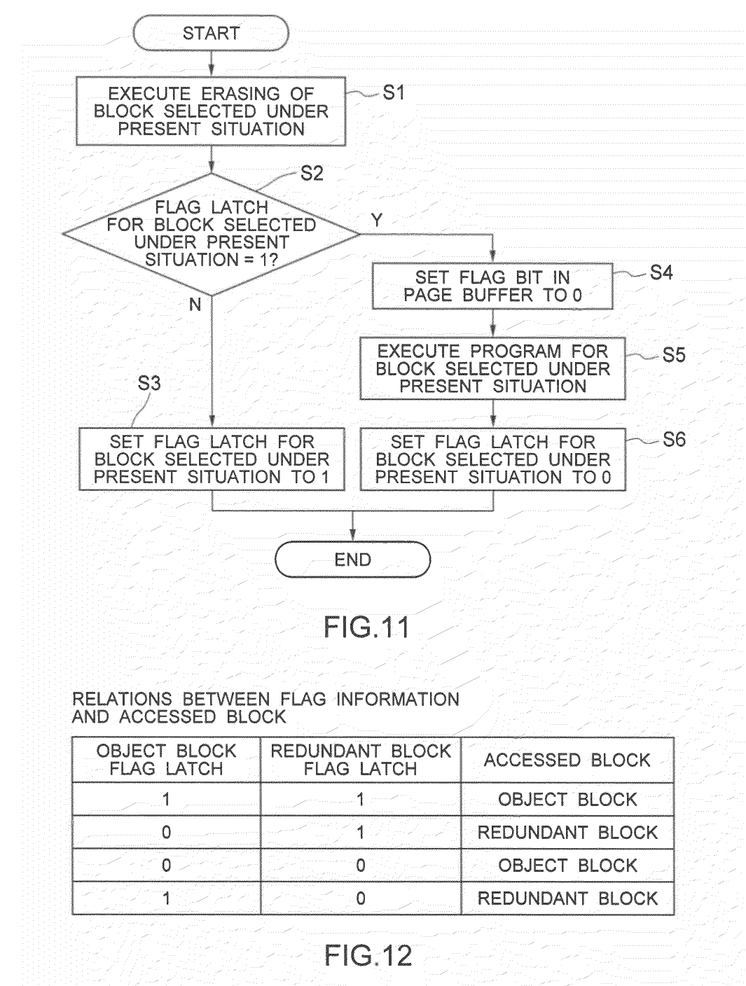

FIG. 11 is a diagram showing an example of a sequence of flag information setting at the time of an erase operation. FIG. 12 is a diagram showing an example of relations between logics of flag latches and blocks to be accessed.

As shown in FIG. 11, if an erase operation of a block selected under the present situation (an object block or a redundant block) is executed (step S1), the flag generation circuit 112 makes a decision whether a flag latch of the selected block (the object block flag latch or the redundant block flag latch) is “1” (step S2).

At the step S2, unless the flag information latched in the flag latch is “1,” the flag generation circuit 112 sets a flag latch for a block selected under the present situation to “1” (step S3).

On the other hand, if the flag information latched in the flag latch is “1” at the step S2, the flag generation circuit 112 sets “0” in the flag bit in the page buffer 2b as flag information (step S4). And the flag generation circuit 112 programs the flag information which is set in the page buffer 2b, into a flag bit region in a block selected under the present situation (step S5).

Then, the flag generation circuit 112 sets a flag latch for the block selected under the present situation to “0” (step S6).

Owing to the flow described heretofore, the flag information is set in the flag bit region and the flag latch for the block at the time of an erase operation.

The block changeover circuit 111 controls selection of a block to be accessed on the basis of a table (FIG. 12) indicating relations between the flag information which is set in this way and access blocks.

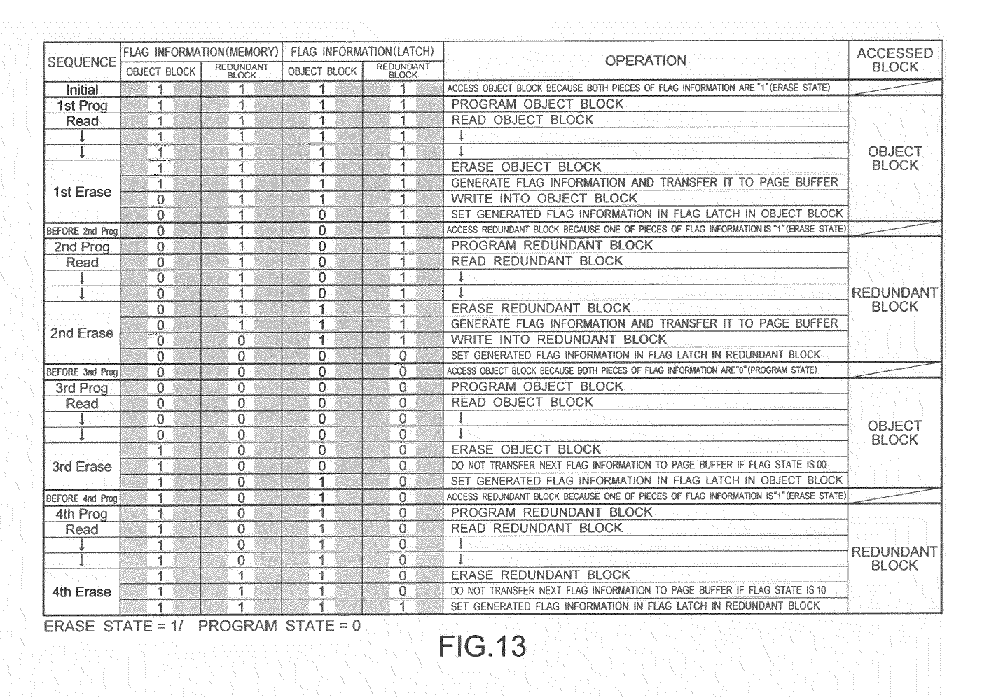

FIG. 13 is a diagram showing a sequence of a method for generating flag information and writing the flag information into the block and the flag latch when erasing data in the block.

In FIG. 13, the flag information is represented by logics which are generated by the flag generation circuit 112, and it is described as to the case where it is stored in the memory cell array and the case where it is stored in the latch.

As shown in FIG. 13, in the initial state, flag information stored in the object block A and the redundant block B in the memory cell array has a value set to “11,” and flag information stored in the object block flag latch 107 and the redundant block flag latch 108 has a value set to “11.”

Since the flag information latched in the object block flag latch 107 and the redundant block flag latch 108 is “11” in this way, the block changeover circuit 111 controls the selection in the block decoder 115 to access the object block A on the basis of the relations shown in FIG. 12 (Initial).

Then, a program operation is executed on the selected object block A (1st Prog).

Then, a readout operation is executed on the selected object block A (Read).

Then, an erase operation is executed on the selected object block A. At this time, “1” represents the erase state. Therefore, the flag information stored in the object block A and the redundant block B remains “11.” In accordance with the sequence shown in FIG. 11, the flag generation circuit 112 generates the flag information “0” of the object block A and transfers it to the page buffer 2b. The flag information “0” which is set in the page buffer 2b is programmed into the flag bit region in the object block A. And the flag information “0” is latched in the object block flag latch 107 (1st Erase).

Then, the flag information stored in the object block A and the redundant block B in the memory cell array has a value set to “01,” and flag information stored in the object block flag latch 107 and the redundant block flag latch 108 has a value set to “01.”

Since the flag information latched in the object block flag latch 107 and the redundant block flag latch 108 is “01” in this way, the block changeover circuit 111 controls the selection in the block decoder 115 to access the redundant block B on the basis of the relations shown in FIG. 12 (Before 2nd Prog).

Then, a program operation is executed on the selected redundant block B (2nd Prog).

Then, a readout operation is executed on the selected redundant block B (Read).

Then, an erase operation is executed on the selected redundant block B. At this time, “1” represents the erase state. Therefore, the flag information stored in the object block A and the redundant block B remains “01.” In accordance with the sequence shown in FIG. 11, the flag generation circuit 112 generates the flag information “0” of the redundant block B and transfers it to the page buffer 2b. The flag information “0” which is set in the page buffer 2b is programmed into the flag bit region in the redundant block B. And the flag information “0” is latched in the redundant block flag latch 108 (2nd Erase).

Then, the flag information stored in the object block A and the redundant block B in the memory cell array has a value set to “00,” and flag information stored in the object block flag latch 107 and the redundant block flag latch 108 has a value set to “00.”

Since the flag information latched in the object block flag latch 107 and the redundant block flag latch 108 is “00” in this way, the block changeover circuit 111 controls the selection in the block decoder 115 to access the object block A on the basis of the relations shown in FIG. 12 (Before 3rd Prog).

Then, a program operation is executed on the selected object block A (3rd Prog).

Then, a readout operation is executed on the selected object block A (Read).

Then, an erase operation is executed on the selected object block A. At this time, “1” represents the erase state. Therefore, the flag information stored in the object block A and the redundant block B becomes “10.” In the case where the flag information latched in the flag latches is “00,” the flag generation circuit 112 does not transfer the flag information to the page buffer 2b, in accordance with the sequence shown in FIG. 11. And the flag generation circuit 112 latches flag information “1” in the object block flag latch 107 (3rd Erase).

Then, the flag information stored in the object block A and the redundant block B in the memory cell array has a value set to “10,” and flag information stored in the object block flag latch 107 and the redundant block flag latch 108 has a value set to “10.”

Since the flag information latched in the object block flag latch 107 and the redundant block flag latch 108 is “10” in this way, the block changeover circuit 111 controls the selection in the block decoder 115 to access the redundant block B on the basis of the relations shown in FIG. 12 (Before 4th Prog).

Then, a program operation is executed on the selected redundant block B (4th Prog).

Then, a readout operation is executed on the selected redundant block B (Read).

Then, an erase operation is executed on the selected redundant block B. At this time, “1” represents the erase state. Therefore, the flag information stored in the object block A and the redundant block B becomes “11.” In the case where the flag information latched in the flag latches is “10,” the flag generation circuit 112 does not transfer the flag information to the page buffer 2b, in accordance with the sequence shown in FIG. 11. And the flag information “1” is latched in the redundant block flag latch 108 (4th Erase).

Thereafter, a similar sequence is executed repeatedly.

When erasing data in a block, flag information is generated and written into a flag data region in the block according to the above-described method. In other words, when conducting an erase operation on one of the object block A and the redundant block B, flag information stored in the flag bit region 1c or flag information stored in the flag bit region 1d is rewritten to cause the block decoder 115 to select the other of the object block A and the redundant block B. In addition, after flag information stored in the flag bit region is or flag information stored in the flag bit region 1d is rewritten, the rewritten flag information stored in the flag bit region 1c or rewritten flag information stored in the flag bit region 1d is latched in the object block flag latch 107 or the redundant block flag latch 108.

As a result, the block changeover circuit 111 can make a decision as to the changeover state between an object block and a redundant block on the basis of flag information stored in the flag data regions.

In other words, the block changeover state can be restored to the state before the power supply is turned off.

By the way, in the above-described method, the number of times of writing in a block is the sum of the number of times of data writing and the number of times of flag writing.

Access to the object block is made equal in ratio to access to the redundant block by the above-described method. In other words, it is possible to automatically disperse the number of times of rewriting of blocks and prolong the life of the nonvolatile memory.

An example of a method for generating and writing the flag information when writing block data will now be described.

According to this method, a flag write operation is not needed in the erase operation and a flag is written when writing data. In this method, the number of times of writing in a block is limited to the number of times of data writing.

FIG. 14 is a diagram showing an example of a sequence for setting flag information into a selected block at the time of a write operation. FIG. 15 is a diagram showing an example of a sequence for setting flag information into flag latches at the time of an erase operation. FIG. 16 is a diagram showing an example of relations between logics of the flag latches and blocks to be accessed.

As shown in FIG. 14, the flag generation circuit 111 generates flag information “0” for a block (the object block or the redundant block) selected under the present situation and transfers the flag information “0” to the page buffer 2b before execution of a program operation (step S11).

Then, the flag generation circuit 111 programs flag information “0” for the block selected under the present situation (step S12).

Owing to the flow described heretofore, the flag information is set in the flag bit region in the block.

In setting flag information into the flag latch at the time of an erase operation, first, an erase operation of the block selected under the present situation is executed, as shown in FIG. 15 (step S21). As a result, flag information stored in the flag data region in the block selected under the present situation becomes “1,” which indicates the erase state.

Then, the logic of flag information retained in each of the object block flag latch and the redundant block flag latch is inverted (the object block flag latch and the redundant block flag latch are updated) (step S22).

Owing to the flow described heretofore, flag information latched in the object block flag latch 107 and the redundant block flag latch 108 is set at the time of an erase operation to cause the next selected block to become the redundant block B if the block selected under the present situation is the object block A, or cause the next selected block to become the object block A if the block selected under the present situation is the redundant block B.

In this way, the block changeover circuit 111 controls selection of a block to be accessed on the basis of a table (FIG. 16) showing relations between the flag information which is set and the accessed block.

By the way, if the power supply is turned off between execution of erasing on the object block A and next writing, the redundant block B does not become the object of writing according to the table shown in FIG. 16. In accordance with the write commands already described with reference to FIGS. 3 and 4, therefore, flag information is written into flag bit regions of the object block and the redundant block, respectively, in the memory cell array 1. The flag information which is to be write data is transferred from the flag generation circuit 112 to the page buffer 2b.

As for an operation for writing the flag information with the dedicated command shown in FIGS. 3 and 4, the main control circuit 114 receives a signal recognized by the command analysis circuit 102, and controls the block changeover circuit 111, the flag generation circuit 112, and the counter 113.

The counter 113 conducts an operation indicating a set into which the flag information is to be written. As for a write operation corresponding to one set, the block changeover circuit 111 selects addresses of the object block and the redundant block as an input to the block decoder, and write data is transferred from the flag generation circuit 112 to the page buffer 2b.

If the flag information is set in the page buffer 2b, the main control circuit 114 exercises the same control (such as voltage control) as the control in the ordinary writing, and flag information is written into the flag data regions 1c and 1d in the memory cell array 1.

In writing corresponding to one set, writing is conducted respectively into the object block and the redundant block. Therefore, writing is conducted twice for one set.

When the power supply is turned on, the flag information stored in the flag bit region 1c or the flag information stored in the flag bit region 1d is rewritten, and the flag information obtained by rewriting is latched in the object block flag latch 107 or the redundant block flag latch 108.

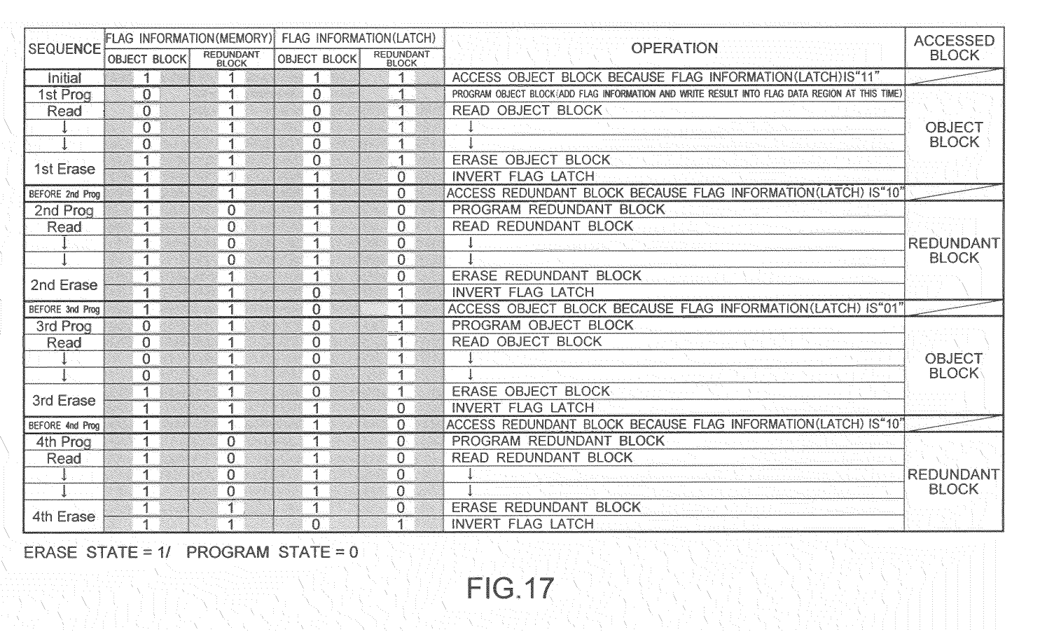

FIG. 17 is a diagram showing a sequence of a method for generating flag information and writing the flag information into the block when writing data into the block.

In FIG. 17, the flag information is represented by logics which are generated by the flag generation circuit 112, and it is described as to the case where it is stored in the memory cell array (memory) and the case where it is stored in the latch.

As shown in FIG. 17, in the initial state, flag information stored in the object block A and the redundant block B in the memory cell array has a value set to “11,” and flag information stored in the object block flag latch 107 and the redundant block flag latch 108 has a value set to “11.”

Since the flag information latched in the object block flag latch and the redundant block flag latch is “11” in this way, the block changeover circuit 111 controls the selection in the block decoder 115 to access the object block A on the basis of the relations shown in FIG. 16 (Initial).

Then, a program operation is executed on the selected object block A (1st Prog). At this time, the flag information “0” generated by the flag generation circuit 112 is stored in the flag bit region in the object block A and the object block flag latch 107 in accordance with the sequence shown in FIG. 14.

In other words, at the time of a write operation on one of the object block A and the redundant block B, flag information stored in the flag bit region 1c or the preceding flag information stored in the flag bit region 1d is rewritten.

As a result, flag information for accessing the object block A selected under the present situation is stored in the first and second flag bit regions 1c and 1d.

Then, a readout operation is executed on the selected object block A (Read).

Then, an erase operation is executed on the selected object block A. At this time, “1” represents the erase state. Therefore, the flag information stored in the object block A and the redundant block B becomes “11.” In accordance with the sequence shown in FIG. 15, the flag generation circuit 112 inverts logics of the flag information latched in the object block flag latch 107 and the redundant block flag latch 108 (1st Erase).

Then, the flag information stored in the object block A and the redundant block B in the memory cell array has a value set to “11,” and flag information stored in the object block flag latch 107 and the redundant block flag latch 108 has a value set to “10.”

Since the flag information latched in the object block flag latch 107 and the redundant block flag latch 108 is “10” in this way, the block changeover circuit 111 controls the selection in the block decoder 115 to access the redundant block B on the basis of the relations shown in FIG. 16 (Before 2nd Prog).

Then, a program operation is executed on the selected redundant block B (2nd Prog). At this time, flag information “0” generated by the flag generation circuit 112 is stored in the flag bit region in the redundant block B and the redundant block flag latch 108 in accordance with the sequence shown in FIG. 14.

In other words, at the time of a write operation on one of the object block A and the redundant block B, flag information stored in the flag bit region is or the preceding flag information stored in the flag bit region 1d is rewritten.

As a result, flag information for accessing the redundant block B selected under the present situation is stored in the first and second flag bit regions 1c and 1d.

Then, a readout operation is executed on the selected redundant block B (Read).

Then, an erase operation is executed on the selected redundant block B. At this time, “1” represents the erase state. Therefore, the flag information stored in the object block A and the redundant block B becomes “11.” In accordance with the sequence shown in FIG. 15, the flag generation circuit 112 inverts logics of the flag information latched in the object block flag latch 107 and the redundant block flag latch 108 (2nd Erase).

Then, the flag information stored in the object block A and the redundant block B in the memory cell array has a value set to “11,” and flag information stored in the object block flag latch 107 and the redundant block flag latch 108 has a value set to “01.”

Since the flag information latched in the object block flag latch 107 and the redundant block flag latch 108 is “01” in this way, the block changeover circuit 111 controls the selection in the block decoder 115 to access the object block A on the basis of the relations shown in FIG. 16 (Before 3rd Prog).

Then, a program operation is executed on the selected object block A (3rd Prog). At this time, flag information “0” generated by the flag generation circuit 112 is stored in the flag bit region in the object block A and the object block flag latch 107 in accordance with the sequence shown in FIG. 14.

In other words, at the time of a write operation on one of the object block A and the redundant block B, flag information stored in the flag bit region 1c or the preceding flag information stored in the flag bit region 1d is rewritten.

As a result, flag information for accessing the redundant block A selected under the present situation is stored in the first and second flag bit regions 1c and 1d.

Then, a readout operation is executed on the selected redundant block A (Read).

Then, an erase operation is executed on the selected redundant block A. At this time, “1” represents the erase state. Therefore, the flag information stored in the object block A and the redundant block B becomes “11.” In accordance with the sequence shown in FIG. 15, the flag generation circuit 112 inverts logics of the flag information latched in the object block flag latch 107 and the redundant block flag latch 108 (3rd Erase).

Then, the flag information stored in the object block A and the redundant block B in the memory cell array has a value set to “11,” and flag information stored in the object block flag latch 107 and the redundant block flag latch 108 has a value set to “10.”

Since the flag information latched in the object block flag latch 107 and the redundant block flag latch 108 is “10” in this way, the block changeover circuit 111 controls the selection in the block decoder 115 to access the redundant block B on the basis of the relations shown in FIG. 16 (Before 4th Prog).

Then, a program operation is executed on the selected object block B (4th Prog). At this time, flag information “0” generated by the flag generation circuit 112 is stored in the flag bit region in the redundant block B and the redundant block flag latch 108 in accordance with the sequence shown in FIG. 14.

In other words, at the time of a write operation on one of the object block A and the redundant block B, flag information stored in the flag bit region 1c or the preceding flag information stored in the flag bit region 1d is rewritten.

As a result, flag information for accessing the redundant block B selected under the present situation is stored in the first and second flag bit regions 1c and 1d.

Then, a readout operation is executed on the selected redundant block B (Read).

Then, an erase operation is executed on the selected redundant block B. At this time, “1” represents the erase state. Therefore, the flag information stored in the object block A and the redundant block B becomes “11.” In accordance with the sequence shown in FIG. 15, the flag generation circuit 112 inverts logics of the flag information latched in the object block flag latch 107 and the redundant block flag latch 108 (4th Erase).

Thereafter, a similar sequence is executed repeatedly.

In this example, access to the object block is made equal in ratio to access to the redundant block unless the power supply is turned off. In other words, it is possible to automatically disperse the number of times of rewriting of each block and prolong the life of the nonvolatile memory.

According to the nonvolatile memory in the present embodiment, it is possible to automatically disperse the number of times of rewriting on blocks in the memory cell array as described heretofore.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile memory comprising:
a memory cell array comprising an object block which includes a first data bit region capable of storing input data and a first flag bit region capable of storing first flag information, a redundant block which includes a second data bit region capable of storing input data and a second flag bit region capable of storing second flag information, and a special block including a special bit region capable of storing an object block address of the object block;
an object block retention part configured to retain the object block address;
an object block flag storage part configured to store the first flag information therein;
a redundant block flag storage part configured to store the second flag information;
a coincidence detection circuit configured to detect whether a block address which is input coincides with the object block address retained in the object block retention part; and
a block changeover circuit configured to control selection of one of the object block and the redundant block on the basis of the first and second flag information when the coincidence detection circuit has detected that the input block address coincides with the object block address.

2. The nonvolatile memory according to claim 1, further comprising a table indicating relations between the flag information which is set in this way and access blocks, wherein
when the coincidence detection circuit has detected that the input block address coincides with the object block address, the block changeover circuit controls selection of one of the object block and the redundant block on the basis of the table.

3. The nonvolatile memory according to claim 1, further comprising a block decoder which selects a block in the memory cell array, wherein
the block changeover circuit causes the block decoder to select one of the object block and the redundant block on the basis of the first and second flag information, when the coincidence detection circuit has detected that the input block address coincides with the object block address.

4. The nonvolatile memory according to claim 1, further comprising a redundant block retention part which is adapted to retain the redundant block address, wherein
the special bit region of the special block including is capable of storing a redundant block address of the redundant block, and
the block changeover circuit causes the block decoder to select one of the object block and the redundant block by using the object block address or the redundant block address on the basis of the first and second flag information, when the coincidence detection circuit has detected that the input block address coincides with the object block address.

5. The nonvolatile memory according to claim 2, further comprising a redundant block retention part which is adapted to retain the redundant block address, wherein
the special bit region of the special block including is capable of storing a redundant block address of the redundant block, and
the block changeover circuit causes the block decoder to select one of the object block and the redundant block by using the object block address or the redundant block address on the basis of the first and second flag information, when the coincidence detection circuit has detected that the input block address coincides with the object block address.

6. The nonvolatile memory according to claim 2, wherein
when conducting an erase operation on one of the object block and the redundant block, the first flag information stored in the first flag bit region or the second flag information stored in the second flag bit region is rewritten to cause the block decoder to select the other of the object block and the redundant block.

7. The nonvolatile memory according to claim 5, wherein
after the first flag information stored in the first flag bit region or the second flag information stored in the second flag bit region is rewritten, the first flag information stored in the first flag bit region or the second flag information stored in the second flag bit region which is obtained by the rewriting is stored in the object block flag storage part or the redundant block flag storage part.

8. The nonvolatile memory according to claim 1, wherein,
when conducting a write operation on one of the object block and the redundant block, the first flag information stored in the first flag bit region or the second flag information stored in the second flag bit region is rewritten.

9. The nonvolatile memory according to claim 2, wherein,
when conducting a write operation on one of the object block and the redundant block, the first flag information stored in the first flag bit region or the second flag information stored in the second flag bit region is rewritten.

10. The nonvolatile memory according to claim 3, wherein,
when conducting a write operation on one of the object block and the redundant block, the first flag information stored in the first flag bit region or the second flag information stored in the second flag bit region is rewritten.

11. The nonvolatile memory according to claim 4, wherein,
when conducting a write operation on one of the object block and the redundant block, the first flag information stored in the first flag bit region or the second flag information stored in the second flag bit region is rewritten.

12. The nonvolatile memory according to claim 7, wherein,
when power supply is turned on, the first flag information stored in the first flag bit region or the second flag information stored in the second flag bit region is rewritten, and the first flag information or the second flag information obtained by the rewriting is stored in the object block flag storage part or the redundant block flag storage part.

13. The nonvolatile memory according to claim 1, further comprising a flag generation circuit which is adapted to generate the first flag information and the second flag information.

14. The nonvolatile memory according to claim 2, further comprising a flag generation circuit which is adapted to generate the first flag information and the second flag information.

15. The nonvolatile memory according to claim 3, further comprising a flag generation circuit which is adapted to generate the first flag information and the second flag information.

16. The nonvolatile memory according to claim 4, further comprising a flag generation circuit which is adapted to generate the first flag information and the second flag information.

17. The nonvolatile memory according to claim 1, wherein the redundant block is adapted to not to allow address thereof to be specified by an external command.

18. The nonvolatile memory according to claim 2, wherein the redundant block is adapted to not to allow address thereof to be specified by an external command.

19. The nonvolatile memory according to claim 7, wherein,
after the second flag information is rewritten, the object block flag storage part and the redundant block flag storage part are updated after an erase operation.

20. The nonvolatile memory according to claim 1, further comprising a counter that a value is set in, the value indicating the number of sets of the object block and redundant block,
wherein setting of the object block address or the redundant block address, the first flag information, and the second flag information is conducted repeatedly as many times as a value which is set in the counter.
